(19) United States
(12) Patent Application Publication
(10) Pub. No.: US 2026/0168090 A1
(43) Pub. Date: Jun. 18, 2026

(54) INTERLOCK ARRANGEMENTS, SEMICONDUCTOR PROCESSING SYSTEMS INCLUDING INTERLOCK ARRANGEMENTS, INTERLOCK KITS, AND RELATED METHODS OF INTERLOCKING FLUID SOURCES

(71) Applicant: ASM IP Holding B.V., Almere (NL)

(72) Inventors: Saikat Banerjee, Tempe, AZ (US); Jingcheng Zhou, Tempe, AZ (US); Dibya Gautam, Mesa, AZ (US); Fan Gao, Chandler, AZ (US); Yue Zhao, Chandler, AZ (US); Mingyang Ma, Phoenix, AZ (US); Junwei Su, Chandler, AZ (US)

(21) Appl. No.: 19/419,575

(22) Filed: Dec. 15, 2025

Related U.S. Application Data
(60) Provisional application No. 63/735,604, filed on Dec. 18, 2024.

(51) Int. Cl. C23C 16/44; C23C 16/458; C23C 16/52; H10P 72/00

(52) U.S. Cl. CPC C23C 16/4405; C23C 16/4412; C23C 16/4583; C23C 16/52; H10P 72/0402

(57) ABSTRACT

An interlock arrangement includes a signal lead, a first mechanical switch, and a second mechanical switch. The signal lead has a first end and a second end. The first mechanical switch is coupled to the first end of the signal lead and has a normally-closed position and an open position. The second mechanical switch couples the first mechanical switch to the second end of the signal lead and has a normally-open position and a closed position. Semiconductor processing systems and methods including and/or performed at the interlock arrangement are also described.

### CROSS-REFERENCE TO RELATED APPLICATIONS

This application is a nonprovisional of, and claims priority to and the benefit of, U.S. Provisional Patent Application No. 63/735,604, filed Dec. 18, 2024 and entitled “INTERLOCK ARRANGEMENTS, SEMICONDUCTOR PROCESSING SYSTEMS INCLUDING INTERLOCK ARRANGEMENTS, INTERLOCK KITS, AND RELATED METHODS OF INTERLOCKING FLUID SOURCES,” which is hereby incorporated by reference herein.

### FIELD OF INVENTION

The present disclosure generally relates to fluid systems, and more particularly to controlling the flow of fluids from fluid sources in fluid systems.

### BACKGROUND OF THE DISCLOSURE

Films are commonly deposited onto substrates, such as during the fabrication of semiconductor devices. Film deposition is generally accomplished by supporting a substrate within a reaction chamber, heating the substrate to a desired deposition temperature, and contacting the substrate with a material layer precursor under environmental conditions (e.g., temperature and pressure) selected to cause a film to deposit onto the substrate. Once the film develops a desired property the substrate is typically removed from the reaction chamber and sent on for further processing, as appropriate for the device being fabricated using the film. In some deposition operations an etchant may be provided to an exhaust of the reaction chamber and employed to maintain pressure during deposition of the film onto the substrate, such as to remove accreted material from within the exhaust conduit that could otherwise occlude the exhaust conduit. Countermeasures may be employed to limit (or eliminate entirely) the risk that the etchant backstream into the reaction chamber, potentially damaging reaction chamber components.

Such methods and systems have generally been considered suitable for their intended purpose. However, there remains a need in the art for improved interlock arrangements, semiconductor processing systems including interlock arrangements, interlock kits, and related methods of interlocking fluid sources. The present disclosure provides a solution to this and other needs.

### SUMMARY OF THE DISCLOSURE

An interlock arrangement is provided. The interlock arrangement may include a signal lead having a first end and a second end. The interlock arrangement may further include a first mechanical switch coupled to the first end of the signal lead. The first mechanical switch may have a normally-closed position and an open position. The interlock arrangement may further include a second mechanical switch coupling the first mechanical switch to the second end of the signal lead. The second mechanical switch may have a normally-open position and a closed position.

In addition to one or more of the features described above, or as an alternative, further examples may include a first relay including the first mechanical switch. The first relay may further include a first relay housing enclosing the first mechanical switch. The first relay may further include a first relay coil arranged within the first relay housing configured to move the first mechanical switch between the normally-closed position and the open position when energized.

In addition to one or more of the features described above, or as an alternative, further examples may include a power supply lead connected to the first relay coil, and a power return lead coupled to the first relay coil and, therethrough, to the power supply lead.

In addition to one or more of the features described above, or as an alternative, further examples may include a valve-open switch coupled to the power return lead, which may be configured to electrically couple the return lead to the first relay when a manual valve is moved to a valve open position.

In addition to one or more of the features described above, or as an alternative, further examples may include that the first relay further includes a first paired mechanical switch arranged within the first relay housing. The first paired mechanical switch may have a normally-open position and a closed position. the first relay coil may be configured to move the first paired mechanical switch between the normally-open position and the closed position when energized.

In addition to one or more of the features described above, or as an alternative, further examples may include a valve-open switch coupling the first relay coil to the first paired mechanical switch. Further examples may further include an analog-to-digital converter coupled to the first paired mechanical switch and, therethrough, to the valve-open switch.

In addition to one or more of the features described above, or as an alternative, further examples may include a second relay which may include the second mechanical switch. The second relay may further include a second relay housing enclosing the second mechanical switch. The second relay may further include a second relay coil arranged within the second relay housing configured to move the second mechanical switch between the normally-open position and the closed position when energized.

In addition to one or more of the features described above, or as an alternative, further examples may further include a power supply lead connected to the second relay coil, and a power return lead coupled to the second relay coil and therethrough to the power supply lead.

In addition to one or more of the features described above, or as an alternative, further examples may further include a valve closed switch coupled to the power return lead, which may be configured to electrically couple the power return lead to the second relay when a manual valve is moved to a valve closed position.

In addition to one or more of the features described above, or as an alternative, further examples may further include that the second relay further includes a second paired mechanical switch arranged within the second relay housing. The second paired mechanical switch may have a normally-open position and a closed position. The second relay coil may be configured to move the second paired mechanical switch between the normally-open position and the closed position when energized.

In addition to one or more of the features described above, or as an alternative, further examples may further include a valve-closed switch coupling the second relay coil to the second paired mechanical switch, and an analog-to-digital converter coupled to the second paired mechanical switch and, therethrough, to the valve-closed switch.

In addition to one or more of the features described above, or as an alternative, further examples may further include a manual valve. The manual valve may include a valve body having an inlet port and an outlet port. The manual valve may further include a valve member supported for movement within the valve body between an open position and a closed position. The inlet port may be fluidly coupled to the outlet port in the open position. The inlet port may be fluidly separated from the outlet port in the closed position. The manual valve may further include a valve-open switch operably associated with the valve member and configured to electrically close when the valve member is in the open position. The manual valve may further include a valve-closed switch operably associated with the valve member and configured to electrically close when the valve member is in the closed position. The valve-open switch may be operably associated with the first mechanical switch. The valve-closed switch may be operably associated with the second mechanical switch. Additionally, both the valve-open switch and the valve-closed switch may be electrically open when the valve member is between the open position and the closed position.

In addition to one or more of the features described above, or as an alternative, further examples may include a signaling relay. The signaling relay may include a signaling relay housing. The signaling relay may further include a mechanical signaling switch arranged within the signaling relay housing and coupling the first end of the signal lead to the first mechanical switch. The mechanical signaling switch may have a normally-open position and a closed position. The signaling relay may further include a signaling coil arranged within the signaling relay housing and configured to move the mechanical signaling switch to the closed position when energized. The interlock arrangement may include a signaling supply lead connected to the signaling coil and configured to couple the signaling coil to a current source, and a signaling return lead connected to the signaling coil and therethrough to the signaling supply lead, the signaling return lead configured to couple the signaling coil to the current source.

In addition to one or more of the features described above, or as an alternative, further examples may include a halogen-containing fluid source coupled to the second end of the signal lead and, therethrough, to the first end of the signal lead through the first mechanical switch and the second mechanical switch. The halogen-containing fluid source may be configured to flow a halogen-containing fluid to a semiconductor processing system when both the first mechanical switch and the second mechanical switch electrically connect the first end of the signal lead to the second end of the signal lead.

A semiconductor processing system is provided. The semiconductor processing system may include a chamber body coupled to an exhaust source by an exhaust conduit. The semiconductor processing system may further include a substrate support arranged within the chamber body and supported for rotation therein for rotation about a rotation axis. The semiconductor processing system may further include a union along the exhaust conduit and coupling a halogen-containing fluid source to the exhaust conduit. The semiconductor processing system may further include a manual valve arranged along the exhaust conduit between the chamber body and the union. The manual valve may include a valve body having an inlet port and an outlet port. The manual valve may further include a valve member supported for movement within the valve body between an open position and a closed position. The inlet port may be fluidly coupled to the outlet port in the open position. The inlet port may be fluidly separated from the outlet port in the closed position. The semiconductor processing system may further include an interlock arrangement. The interlock arrangement may include a signal lead having a first end and a second end. The interlock arrangement may further include a first mechanical switch coupled to the first end of the signal lead. The first mechanical switch may have a normally-closed position and an open position. The interlock arrangement may further include a second mechanical switch coupling the first mechanical switch to the second end of the signal lead. The second mechanical switch may have a normally-open position and a closed position. The semiconductor processing system may further include a valve-open switch operably associated with the valve member and configured to electrically close when the valve member is in the open position. The semiconductor processing system may further include a valve-closed switch operably associated with the valve member and configured to electrically close when the valve member is in the closed position. The valve-open switch may be operably associated with the first mechanical switch. The valve-closed may be operably associated with the second mechanical switch. Both the valve-open switch and the valve-closed switch may be electrically open when the valve member is between the open position and the second position.

In addition to one or more of the features described above, or as an alternative, further examples may include a silicon-containing precursor source coupled to the exhaust conduit by the chamber body. The silicon-containing precursor source may include a silicon-containing precursor selected from a group consisting of silane, disilane, trisilane, dichlorosilane, and trichlorosilane. The halogen-containing fluid source may include a halogen-containing fluid selected from a group consisting of hydrochloric acid, chlorine gas, and chlorine trifluoride.

In addition to one or more of the features described above, or as an alternative, further examples may include a mechanical signaling switch coupling the first end of the signal lead to the first mechanical switch. Further examples may include a power source coupled to the first end of the signal lead. Further examples may include a controller operatively coupled to the mechanical signaling switch and responsive to instructions recorded on a memory to: receive a user input from user input; and electrically couple the power source to the first mechanical switch using the signaling switch responsive to the user input to flow a halogen-containing fluid to the union. One of the first mechanical switch or the second mechanical switch may electrically separate the power source from the second end of the signal lead when the valve member is not at the closed position to interlock flow of the halogen-containing fluid to the exhaust conduit.

A method of interlocking a halogen-containing fluid source is provided. The method may be performed at an interlock arrangement that may include a signal lead having a first end and a second end. The interlock arrangement may further include a first mechanical switch coupled to the first end of the signal lead. The first mechanical switch may have a normally-closed position and an open position. The interlock arrangement may further include a second mechanical switch coupling the first mechanical switch to the second end of the signal lead. The second mechanical switch may have a normally-open position and a closed position. The method may include receiving a user input at a user input of a controller. Responsive to receipt of the user input, applying a voltage to the first end of the signal lead to flow a halogen-containing fluid from the halogen-containing fluid source. Flowing no halogen-containing fluid from the halogen-containing fluid source when the first mechanical switch is in the open position and/or the second mechanical switch is in the normally-open position. Flowing the halogen-containing fluid when the first mechanical switch is in the normally-closed position and the second mechanical switch is in the closed position by electrically coupling the second end of the signal lead to the first end of the signal through the first mechanical switch and the second mechanical switch.

In addition to one or more of the features described above, or as an alternative, further examples may include that the interlock arrangement includes a valve-open switch and a valve-closed switch operably associated with a valve member of a manual valve arranged along an exhaust conduit. The method may further include moving the valve member to the open position such that the valve open switch closes, whereby the second mechanical switch remains in the normally-open position and the second mechanical switch separates the second end of the signal lead from the first end of the signal lead to interlock the halogen-containing fluid source. The method may further include flowing a silicon-containing precursor through the valve and into the exhaust conduit while the halogen-containing fluid source is interlocked such that no halogen-containing fluid flows from the halogen-containing source to the exhaust conduit.

In addition to one or more of the features described above, or as an alternative, further examples may include moving the valve member from the open position to a location intermediate the open position and the closed position, whereby the valve-open switch opens and the second mechanical switch remains in the normally-open position and the second mechanical switch separates the second end of the signal lead from the first end of the signal lead to interlock the halogen-containing fluid source. The method may further include flowing additional silicon-containing precursor through the valve and into the exhaust conduit while the halogen-containing fluid source remains interlocked such that no halogen-containing fluid flows from the halogen-containing source to the exhaust conduit.

In addition to one or more of the features described above, or as an alternative, further examples may include moving the valve member to the closed position, whereby the valve-closed switch closes and the second mechanical switch moves to the closed position such that the second end of the signal lead is electrically connected to the first end of the signal lead by both the first mechanical switch and the second mechanical switch. The method may further include flowing the halogen-containing fluid into the exhaust conduit to remove silicon-containing precursor and/or residue from within the exhaust conduit without backflowing the halogen-containing fluid into a chamber body coupled to the exhaust conduit by the manual valve.

An interlock kit for a halogen-containing fluid source is provided. The interlock kit may include a signal lead having a first end and a second end. The first end of the signal lead may be configured to couple a power source. The second end of the signal lead may be configured to couple to the halogen-containing fluid source. The interlock kit may further include a first mechanical switch configured to couple to the first end of the lead. The first mechanical switch may have a normally-closed position and an open position. The interlock kit may further include a second mechanical switch configured to couple the first mechanical switch to the second end of the lead. The second mechanical switch may have a normally-open position and a closed position.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including an interlock arrangement.

FIG. 2 is a portion of the example interlock arrangement of FIG. 1.

FIG. 3A and FIG. 3B are block diagrams of a method of interlocking a halogen-containing fluid source.

FIG. 4 shows example elements of a controller.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

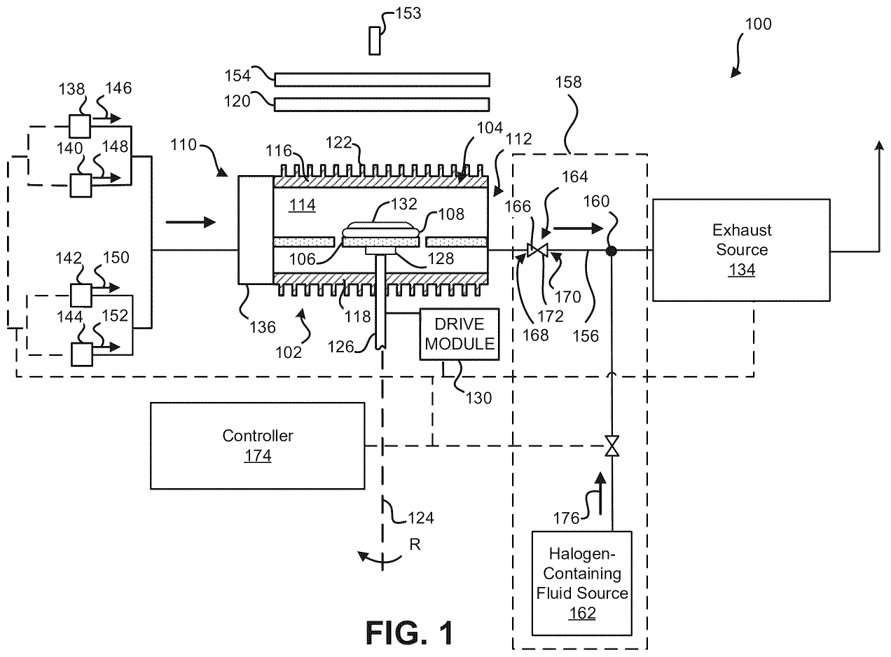

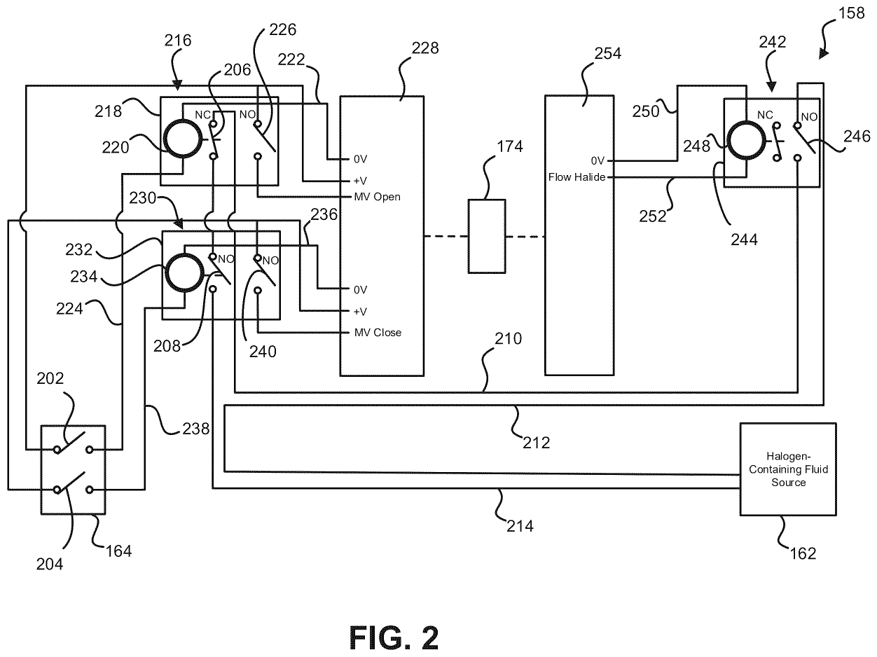

Reference will now be made to the drawings wherein like reference numerals identify similar structural features or aspects of the subject disclosure. For purposes of explanation and illustration, and not limitation, a partial view of an example of a semiconductor processing system including a interlock arrangement in accordance with the present disclosure is shown in FIG. 1 and is designated generally by reference character 100. Other examples of semiconductor processing systems, mixing blocks, fixtures, and related methods of purging mixing blocks in accordance with the present disclosure, or aspects thereof, are provided in FIGS. 2-4, as will be described. The systems and methods of the present disclosure may be used to purge flow channels within mixing blocks employed in fluid systems, such as in mixing blocks used to provide material layer precursors in semiconductor processing systems employed to deposit material layers onto substrates using atomic layer deposition (ALD) or chemical vapor deposition (CVD) techniques, though the present disclosure is not limited to any particular deposition technique or to material layer deposition in general.

Referring to FIG. 1, the semiconductor processing system 100 may include a chamber arrangement 102 including a chamber body 104. The chamber arrangement may further include a substrate support 106 configured to receive a substrate 108. Although a particular example arrangement of the chamber arrangement 102 is shown and described (e.g., a cold wall crossflow-type chamber arrangement), it is to be understood and appreciated that semiconductor processing systems having other types of chamber arrangements may also benefit from the present disclosure.

The chamber body 104 may have an injection end 110 and a longitudinally opposite exhaust end 112, substantially opposed to the injection end 110, and an interior 114. The interior 114 of the chamber body 104 may be bounded by a top wall 116, extending between the injection end 110 and the exhaust end 112 of the chamber body 104, a bottom wall 118 below the top wall 116 and extending between the injection end 110 and the exhaust end 112 of the chamber body 104, a first side wall extending between and/or coupling lateral edges of the top wall 116 and the bottom wall 118 to one another, and a laterally opposite second side wall extending between and/or coupling opposite lateral edges of the top wall 116 and the bottom wall 118 to one another. In example configurations, the top wall 116 and/or the bottom wall 118 may be ribbed. For example, referring to FIG. 1, the top wall 116 and/or the bottom wall 118 may comprise a plurality of ribs extending from an external surface thereof. In other example configurations, the top wall 116 and/or the bottom wall may not be ribbed. In certain example configurations, the chamber body 104, or a portion thereof, may be formed from a substantially transparent material, for example a material transparent to electromagnetic radiation within an infrared waveband, such as a ceramic material like fused silica or quartz. The substantially transparent material may be transmissive to electromagnetic radiation, for example, emitted by a heater element.

The substrate 108 (e.g., wafer) may be disposed and/or supported within the chamber body 104. The substrate 108 may be heated, for example, using the heater element 120, and/or a heater element array. In accordance with certain example configurations, at least a portion of the chamber body 104 may be formed from quartz. As described, the top wall 116 and/or the bottom wall 118 of the chamber body 104 may comprise ribs 122. The ribs 122 may extend outward from one or more of the top wall 116 and the bottom wall 118. The ribs 122 may provide structural support to the chamber body 104 and/or allow the interior 114 of the chamber body 104 to be maintained at relatively low pressure relative to the environment outside of the chamber body 104. In alternative example configurations, the ribs 122 of one or more of the top wall 116 and the bottom wall 118 may be omitted.

As used herein the term “substrate” may refer to any underlying material or materials, including any underlying material or materials that may be modified, or upon which, a device, a circuit, or a material layer (e.g., a film) may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO2), gallium arsenide (GaAs), gallium nitride (GaN), and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

The substrate support 106 may be arranged within the interior 114 of the chamber body 104 and supported therein for rotation R about a rotation axis 124, and may include a substrate support structure. The substrate support 106 may be supported by the support member 128. The substrate support 106 may be arranged along and/or may comprise a rotation axis 124 relative to the support member 128. The substrate support 106 may be disposed in fixed rotation relative to the support member 128. The support member 128 may be in fixed rotation relative to the shaft 126. The shaft 126 may be supported for rotation R about the rotation axis 124. The shaft 126 may extend through the bottom wall 118 of the chamber body 104 and may couple the substrate support 106 and the support member 128 to drive module 130. The drive module 130 may be operably connected to the substrate support 106, for example, via the shaft 126 and the support member 128. The drive module 130 may be configured to rotate the substrate support 106 via the shaft 126 and the support member 128 about the rotation axis 124, for example, during the deposition of a material layer 132 onto the substrate 108. The substrate 108 may comprise a wafer, such as a semiconductor wafer. The material layer 132 may comprise an epitaxial material layer, such as a silicon-containing and/or a germanium-containing material layer. It is also contemplated that, in accordance with certain example configurations, the material layer 132 may be a thick epitaxial material layer formed, for example, during the fabrication of a power electronics device. An example power device may include an insulated gate bipolar transistor semiconductor device. A “thick” layer may comprise a layer having a thickness that is greater than 25 microns, greater than 50 microns, greater than 75 microns, greater than 100 microns, or that is between about 25 microns and about 100 microns.

The semiconductor processing system may further comprise an exhaust source 134. The exhaust source 134 may be connected to the exhaust end 112 of the chamber body 104. The chamber body 104 may be coupled to the exhaust source 134 via an exhaust conduit 156. The exhaust source 134 may be configured to couple the chamber body 104 to an exhaust source, such as a scrubber. In certain example configurations, the chamber body 104 may comprise an exhaust flange extending outward from and about the walls of the chamber body 104. The exhaust source 134 may be connected to the exhaust flange. The semiconductor processing system may further comprise an injection flange 136. The injection flange 136 may be connected to the injection end 110 of the chamber body 104. The injection flange 136 may couple a first precursor source 138, one or more second precursor source 140, a purge/carrier gas source 142, and/or a halide source 144 to the chamber body 104. In certain example configurations, the chamber body 104 may comprise the injection flange 136, for example, extending outward from and about the injection end 110 of the chamber body 104. One or more of the chamber body 104, the injection flange 136, and the exhaust source 134 may be substantially as shown and described in U.S. Patent Application Pub. No. 2010/0116207 A1, filed on Nov. 5, 2009 and titled “Reaction Chamber,” the contents of which are incorporated herein by reference in their entirety.

The first precursor source 138 may be fluidly coupled to the chamber body 104 via the injection flange 136. The first precursor source 138 may be further configured to provide a first precursor 146 to the chamber body 104 (e.g., to the interior 114 of the chamber body 104). In certain example configurations, the first precursor 146 may include a silicon-containing precursor. Examples of silicon-containing precursors may include, by way of non-limiting examples, silane (SiH4), disilane (Si2H6), trisilane (H2Si(SiH3)2), dichlorosilane (H2SiCl2), trichlorosilane (HCl3Si), and higher order silane compounds, such as, for example, tetramethylsilane (Si(CH3)4).

The one or more second precursor source 140 may be fluidly coupled to the chamber body 104 by the injection flange 136. The one or more second precursor source 140 may be configured to provide one or more second precursor 148 to the chamber body 104 (e.g., to the interior 114 of the chamber body 104). In certain example configurations, the one or more second precursor 148 may include a dopant, such as an n-type and/or a p-type dopant-containing precursor. The one or more second precursor 148 may include, for example, a germanium precursor. Examples of germanium precursors may include, by way of non-limiting examples, germane (GeH4), germanium tetrafluoride (GeF4), and tributylgermanium hydride ([CH3(CH2)3]3GeH).

The purge/carrier gas source 142 may be fluidly coupled to the chamber body 104 by the injection flange 136. The purge/carrier gas source 142 may be configured to provide a purge/carrier gas 150 to the chamber body 104 (e.g., to the interior 114 of the chamber body 104). In certain examples, the purge/carrier gas 150 may include hydrogen (H2), helium (He), nitrogen (N2), argon (Ar), and/or krypton (Kr), or a mixture thereof.

The halide source 144 may be fluidly coupled to the interior 114 of the chamber body 104 by the injection flange 136. The halide source 144 may be configured to provide a halide 152 to the chamber body 104 (e.g., an interior 114 of the chamber body 104). In certain examples, the halide 152 may include chlorine. For example, the halide 152 may include hydrochloric acid (HCl) or chlorine (Cl2). Deposition of the material layer 132 onto the substrate 108 may be facilitated and/or aided by supporting the substrate 108 within the chamber body 104 on the substrate support 106, heating the substrate 108 to a predetermined material layer deposition temperature, rotating the substrate 108 using the substrate support 106 about the rotation axis 124, and flowing the first precursor 146 and/or the second precursor 148 across the substrate 108. As the first precursor 146 and/or the second precursor 148 flow across the substrate 108, the material layer 132 may deposit onto the substrate 108. The material layer 132 may deposit on the substrate 108 in accordance with a temperature of the substrate 108. Heating of the substrate 108 may be accomplished via a heating element (e.g., heater element 120) or a heating element array. The heating element 120 and/or heating element array may be positioned outside of the chamber body 104. The heater element 120 or the heater element array may be arranged above the top wall 116 of the chamber body 104. Additionally or alternative, the heater element 120 and/or the heater element array may be radiantly coupled to the substrate support 106 (and the substrate 108) via the walls (e.g., top wall 116 and/or bottom wall 118) of the chamber body 104. A top reflector 154 (e.g., a portion of cooling kit) may be disposed above the heater element 120. The top reflector 154 may be configured to cooperate with the heater element 120, for example, to reflect electromagnetic radiation emitted from the heater element 120 in a direction substantially opposite the chamber body 104, toward the chamber body 104, for example, to radiantly heat the substrate support 106 and/or the substrate 108. An example configuration of the chamber body 104 may be arranged substantially as shown and described in U.S. Application Publication No. 2018/0363139 A1, filed Apr. 25, 2018 and titled “Semiconductor Processing Apparatus and Methods for Calibrating a Semiconductor Processing Apparatus,” the contents of which are incorporated herein by reference in their entirety.

The semiconductor processing system 100 may further comprise one or more pyrometers 153. The pyrometer(s) 153 may be coupled (e.g., optically coupled) to the top reflector 154. Additionally or alternatively, the pyrometer(s) 153 may be configured to record and/or report the temperature of one or more of the chamber body 104, the substrate support 106, and/or the substrate 108 (e.g., wafer).

The semiconductor processing system 100 may further include an interlock arrangement 158. The interlock arrangement 158 may be operational on the exhaust conduit 156, for example, between the exhaust end 112 (e.g., exhaust flange) and the exhaust source 134. The semiconductor processing system 100, for example, at the interlock arrangement 158, may further include a halogen-containing fluid source 162. The semiconductor processing system 100, for example, at the interlock arrangement 158, may further include a union 160. The union 160 may be arranged (e.g., disposed) along the exhaust conduit 156. The union 160 may couple (e.g., fluidly couple) the halogen-containing fluid source 162 to the exhaust conduit 156. For example, the halogen-containing fluid source 162 may be configured to provide a halogen-containing fluid 176 to the exhaust conduit 156 and/or to the exhaust source 134, for example, to clean the exhaust conduit 156 and/or the exhaust source 134 from silicon precursors and/or accretions, for example, from the deposition process.

The semiconductor processing system 100 may further include, for example, at the interlock arrangement 158, a manual valve 164. The manual valve 164 may be arranged (e.g., disposed, connected, etc.) along the exhaust conduit 156, for example, between the chamber body and the union 160. The manual valve 164 may comprise a valve body 166. The valve body 166 may comprise an inlet port 168 and an outlet port 170. The manual valve 164 may further comprise a valve member 172 supported for movement, within the valve body 166, between an open position and a closed position. In an example configuration, the inlet port 168 may be fluidly coupled to the outlet port 170 if (e.g., when) the valve member 172 is in the open position. Additionally, the inlet port 168 may be fluidly separated from the outlet port 170 if (e.g., when) the valve member 172 is in the closed position.

The semiconductor processing system 100 may further comprise a controller 174. The controller 174 may be operatively coupled to one or more of the first precursor source 138, the one or more second precursor source 140, the purge/carrier gas source 142, the halide source 144, the halogen containing fluid source 162, the exhaust source 134, the interlock arrangement 158, and the drive module 130. The controller 174 is described in more detail herein.

FIG. 2 is a portion of the example interlock arrangement 158 of FIG. 1. With reference to FIG. 2, the manual valve 164 may further include a valve-open switch 202. The valve-open switch 202 may be operably associated with a valve member (e.g., valve member 172) and may be configured to electrically close if (e.g., when) the valve member is in the open position. The manual valve 164 may further include a valve-closed switch 204. The valve-closed switch 204 may be operably associated with the valve member and may be configured to electrically close if (e.g., when) the valve member is in the closed position.

The valve-open switch 202 may be operably associated with a first mechanical switch 206. The first mechanical switch may comprise a normally-closed (NC) position and an open position. The valve-closed switch 204 may be operably associated with a second mechanical switch 208. The second mechanical switch 208 may comprise a normally-open (NO) position and a closed position. Both the valve-open switch 202 and the valve-closed switch 204 may be electrically open if (e.g., when) the valve member (e.g., valve member 172) is between the open position and the closed position.

With continued reference to FIG. 2, the interlock arrangement 158 may include a signal lead 210. The signal lead 210 may include a first end 212 (e.g., of the signal lead 210) and a second end 214 (e.g., of the signal lead 210). The first mechanical switch 206 may be coupled to the first end 212 of the signal lead 210. The second mechanical switch 208 may be configured to couple the first mechanical switch 206 to the second end 214 of the signal lead 210.

The interlock arrangement 158 may further include a first relay 216. The first relay 216 may include the first mechanical switch 206. The first relay 216 may further include a first relay housing 218, for example, enclosing the first mechanical switch 206. The first relay 216 may further include a first relay coil 220. The first relay coil 220 may be arranged within the first relay housing 218. The first relay coil 220 may be configured to move the first mechanical switch between the normally-closed (NC) position and the open position, for example, if (e.g., when) energized. A power supply lead 222 may be connected to the first relay coil 220. Additionally, a power return lead 224 may be coupled to the first relay coil 220, and therethrough, to the power supply lead 222. The valve-open switch 202 may be coupled to the power return lead 224. Additionally, the valve-open switch may be configured to electrically couple the power return lead 224 to the first relay 216, for example, if (e.g., when) the manual valve 164 is moved to a valve open position.

The first relay 216 may further include a first paired mechanical switch 226. The first paired mechanical switch 226 may be arranged (e.g., disposed) within the first relay housing 218. The first paired mechanical switch 226 may include a normally-open (NO) position and a closed position. The first relay coil 220 may be configured to move the first paired mechanical switch 226 between the normally-open (NO) position and the closed position, for example, if (e.g., when) energized.

As described, the manual valve 164 may include a valve-open switch 202. The valve-open switch 202 may be configured and/or arranged to couple the first relay coil 220 to the first paired mechanical switch 226. The interlock arrangement 158 may further include an analog-to-digital converter 228 (ADC) (e.g., embodied in one or more circuit boards (e.g., printed circuit boards). The analog-to-digital converter 228 may be coupled to the first paired mechanical switch 226 and, therethrough, to the valve-open switch 202.

The interlock arrangement 158 may further include a second relay 230. The second relay 230 may include the second mechanical switch 208. The second relay 230 may further include a second relay housing 232, for example, enclosing the second mechanical switch 208. Additionally, the second relay 230 may further include a second relay coil 234. The second relay coil 234 may be arranged (e.g., disposed) within the second relay housing 232. The second relay coil 234 may be configured to move the second mechanical switch 208 between the normally-open (NO) position and the closed position, for example, if (e.g., when) energized. In one or more example configurations, the interlock arrangement 158 may further include a second power supply lead 236 connected to the second relay coil 234. Additionally, the interlock arrangement 158 may further include a second power return lead 238 coupled to the second relay coil 234 and, therethrough, to the second power supply lead 236.

As described herein, the interlock arrangement 158 may include a valve-closed switch 204. The valve-closed switch 204 may be coupled to the second power return lead 238. The valve-closed switch 204 may be configured to electrically couple the second power return lead 238 to the second relay 230, for example, if (e.g., when) the manual valve 164 (e.g., via the valve member 172) to a valve closed position.

In one or more example configurations, the second relay 230 may further include a second paired mechanical switch 240. The second paired mechanical switch 240 may be arranged (e.g., disposed) within the second relay housing 232. The second paired mechanical switch 240 may include a normally-open (NO) position and a closed position. The second relay coil 234 may be configured to move the second paired mechanical switch 240 between the normally-open (NO) position and the closed position, for example, if (e.g., when) energized.

As described, the interlock arrangement 158 (e.g., connected to the manual valve 164) may include a valve-closed switch 204. The valve-closed switch 204 may be configured to couple the second relay coil 234 to the second paired mechanical switch 240. Additionally, the analog-to-digital converter 228 may be coupled to the second paired mechanical switch 240 and, therethrough, to the valve-closed switch 204.

The interlock arrangement 158 may further include a signaling relay 242. The signaling relay 242 may further include a signaling relay housing 244. The signaling relay 242 may further include a mechanical signaling switch 246. The mechanical signaling switch 246 may be arranged (e.g., disposed) within the signaling relay housing 244. The mechanical signaling switch 246 may be arranged and/or configured to couple the first end 212 of the signal lead 210 to the first mechanical switch 206. Additionally, the mechanical signaling switch 246 may include a normally-open (NO) position and a closed position. The signaling relay 242 may further include a signaling coil 248. The signaling coil 248 may be arranged (e.g., disposed) within the signaling relay housing 244 and may be configured to move the mechanical signaling switch 246 to the closed position, for example, if (e.g., when) energized. The interlock arrangement 158 may further include a signaling supply lead 250. The signaling supply lead 250 may be connected to the signaling coil 248, and may be configured to couple the signaling coil 248 to a current source (e.g., power source 254), which in turn may include a printed circuit board through which the controller 174 (shown in FIG. 1) communicates with the signaling coil 248. The interlock arrangement 158 may further include a signaling return lead 252. The signaling return lead 252 may be connected to the signaling coil 248 and, therethrough, to the signaling supply lead 250. The signaling return lead 252 may be configured to couple the signaling coil 248 to the current source (e.g., power source 254).

As described, the semiconductor processing system 100 may include, for example, at the interlock arrangement 158 and/or connected to the interlock arrangement 158, a halogen-containing fluid source 162. The halogen-containing fluid source 162 may be coupled to the second end 214 of the signal lead 210. The second end 214 of the signal lead 210 may be coupled through the halogen-containing fluid source 162 to the first end 212 of the signal lead 210 through the first mechanical switch 206 and the second mechanical switch 208. The halogen-containing fluid source 162 may be configured to flow a halogen-containing fluid 176 to the semiconductor processing system (e.g., semiconductor processing system 100 of FIG. 1) (e.g., to the exhaust conduit 156 and/or exhaust source 134 of FIG. 1) if (e.g., when) both the first mechanical switch 206 and the second mechanical switch 208 electrically connect the first end 212 of the signal lead 210 to the second end 214 of the signal lead 210.

With continued reference to FIG. 2, the mechanical signaling switch 246 may couple the first end 212 of the signal lead 210 to the first mechanical switch 206. Additionally, a power source, for example the power source 254, may be connected to the first end 212 of the signal lead 210 through the signaling coil 248.

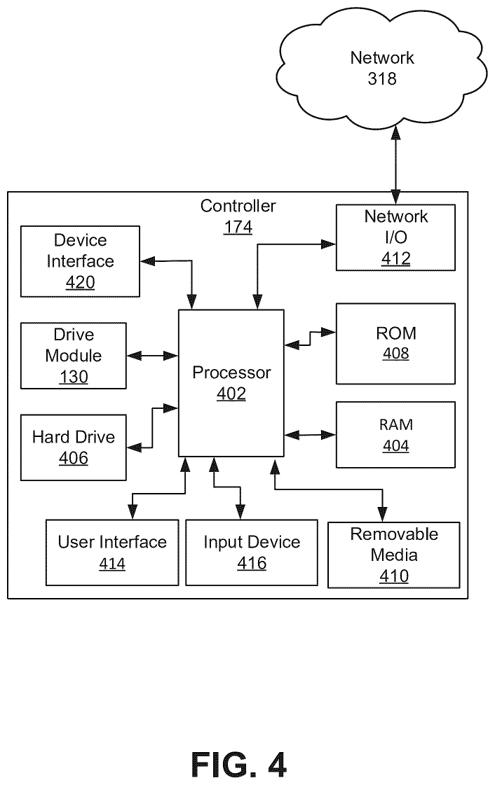

As described, the semiconductor processing system 100 may include a controller 174. The controller 174 may be operatively coupled (either directly or indirectly) to the mechanical signaling switch 246. The controller may comprise one or more processors (e.g., processor 402 of FIG. 4) with memory storing instructions that, when executed by the one or more processors (e.g., responsive to the instructions recorded on the memory) configure the controller 174 to perform one or more of the following processes. For example, the controller 174 may be configured to receive a user input (e.g., from a user input interface and/or device). The controller 174 may be further configured to electrically couple the power source to the first mechanical switch 206 using the mechanical signaling switch 246, for example, in response to the user input, to flow a halogen-containing fluid (e.g., halogen-containing fluid 176) to a union (e.g., union 160 in FIG. 1). Additionally, one of the first mechanical switch 206 or the second mechanical switch 208 electrically separates the power source from the second end 214 of the signal lead 210, for example, if (e.g., when) the valve member (e.g., valve member 172 of FIG. 1) is not at the closed position, for example to interlock flow of the halogen-containing fluid to the exhaust conduit (e.g., exhaust conduit 156 of FIG. 1).

Additionally, it may be appreciated that the interlock arrangement 158 may be provided as an interlock kit. For example, an interlock kit may include the signal lead 210, for example having the first end 212 and the second end 214. The first end 212 of the signal lead 210 may be configured to couple to a power source, and the second end 214 of the signal lead may be configured to couple to the halogen-containing fluid source 162. The interlock kit may further include the first mechanical switch 206 (e.g., as a part of the first relay 216) configured to couple to the first end 212 of the signal lead 210. The first mechanical switch 206 may include a normally-closed (NC) position and an open position. The interlock kit may further include the second mechanical switch 208 (e.g., as a part of the second relay 230) which may be configured to couple the first mechanical switch 206 to the second end 214 of the signal lead 210. The second mechanical switch 208 may include a normally-open (NO) position and a closed position.

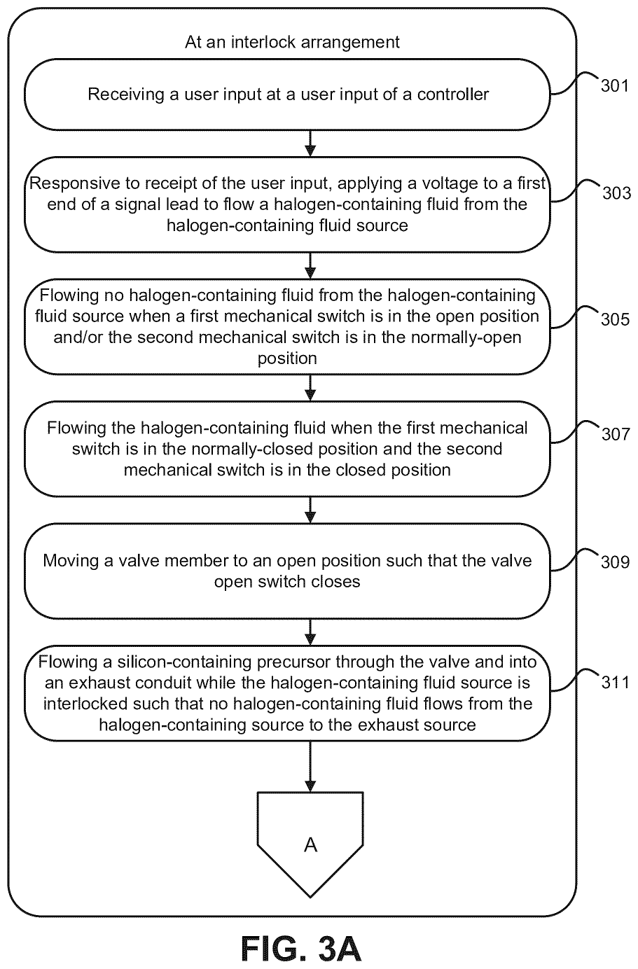

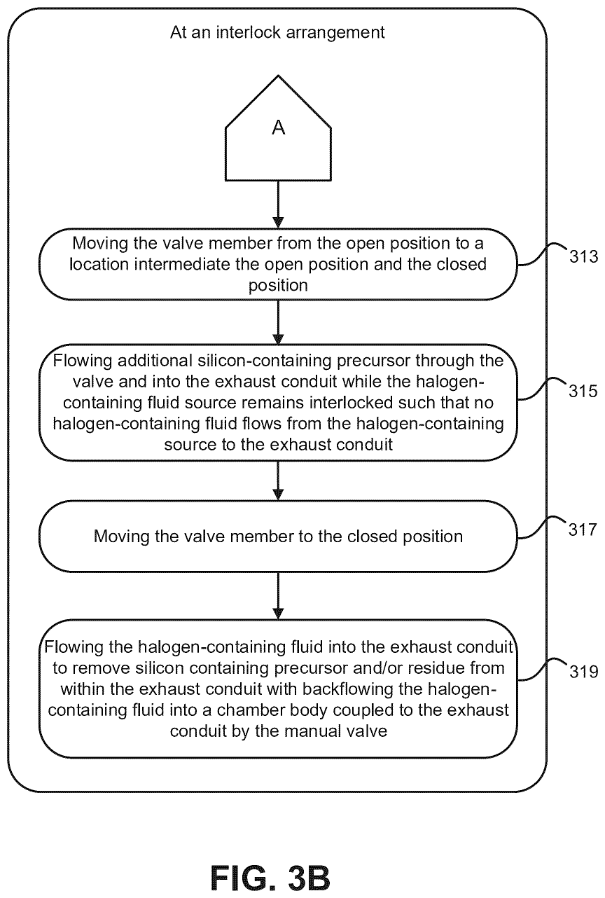

FIGS. 3A and 3B are a block diagram of a method of interlocking a halogen-containing fluid source (e.g., halogen-containing fluid source 162 of FIGS. 1 and 2). One or more steps of the example method of FIGS. 3A-3B may be performed and/or caused by a controller (e.g., controller 174 of FIGS. 1 and 2) or other computing device. Additionally or alternatively, one some or all of the steps of example method of FIGS. 3A-3B may be performed and/or caused by hardware (e.g., manual valve 164, union 160, first relay 216, second relay 230, signaling relay 242, etc.), software (e.g., operational with respect to controller 174), a user, or a combination thereof. Steps of the example method of FIGS. 3A-3B may be omitted, performed in other orders, and/or otherwise modified, and/or one or more additional steps may be added. Additionally or alternatively, one or more steps of the example method of FIGS. 3A and 3B may be performed at and/or by an interlock arrangement (e.g., interlock arrangement 158), for example, at an interlock arrangement that includes: a signal lead (e.g., signal lead 210) having a first end (e.g., first end 212) and a second end (e.g., second end 214); a first mechanical switch (e.g., first mechanical switch 206) coupled to the first end of the signal, where the first mechanical switch comprises a normally-closed (NC) position and an open position; and a second mechanical switch (e.g., second mechanical switch 208) coupling the first mechanical switch to the second end of the signal lead, where the second mechanical switch comprises a normally-open (NO) position and a closed position.

Referring to FIG. 3A, at step 301, a user input may be received. For example, a controller (e.g., controller 174) may receive a user input, for example, at a user interface (e.g., at user interface 414). Additionally or alternatively, the controller may receive an indication of a user input, for example, from the user interface.

At step 303, responsive to receipt of the user input (and/or receipt of the indication of the user input), a voltage may be applied to a first end (e.g., first end 212) of the signal lead (e.g., signal lead 210) to flow a halogen-containing fluid (e.g., halogen-containing fluid 176) from the halogen-containing fluid source (e.g., halogen-containing fluid source 162).

At step 305, halogen-containing fluid may not be flowed (e.g., may be avoided, withheld) from the halogen-containing fluid source (e.g., through an exhaust conduit (e.g., exhaust conduit 156)) if (e.g., when) the first mechanical switch (e.g., first mechanical switch 206) is in the open position and/or the second mechanical switch 208 is in the normally-open (NO) position.

At step 307, the halogen-containing fluid may be flowed (e.g., caused to flow) if (e.g., when) the first mechanical switch is in the normally-closed (NC) position and the second mechanical switch is in the closed position. For example, such a configuration may electrically couple the second end (e.g., second end 214) of the signal lead to the first end of the signal lead through the first mechanical switch and the second mechanical switch.

Additionally or alternatively, the interlock arrangement may include a valve-open switch (e.g., valve-open switch 202) and a valve-closed switch (e.g., valve-closed switch 204). One or more of the valve-open switch and the valve-closed switch may be operably associated with a valve member (e.g., valve member 172) of a manual valve (e.g., manual valve 164) arranged along an exhaust conduit (e.g., exhaust conduit 156). At step 309, the valve member may be moved (e.g., by a user and/or actuator) to the open position such that the valve open switch closes. The second mechanical switch may remain (e.g., be maintained) in the normally-open (NO) position and the second mechanical switch may separate the second end of the signal lead from the first end of the signal lead, for example, to interlock the halogen-containing fluid source (e.g., from flowing, for example, through the exhaust conduit).

At step 311, a silicon-containing precursor (e.g., first precursor 146) may be flowed (e.g., may be cause and/or allowed to flow) through the manual valve and into the exhaust conduit (e.g., exhaust conduit 156) while the halogen-containing fluid source is (e.g., remains) interlocked such that no halogen-containing fluid flows from the halogen-containing fluid source to the exhaust conduit.

Referring to FIG. 3B, at step 313, the valve member may be moved (e.g., by a user and/or actuator) from the open position to a location intermediate the open position and the closed position. The valve member may be moved such that the valve-open switch opens and the second mechanical switch remains in the normally-open (NO) position and the second mechanical switch separates the second end of the signal lead from the first end of the signal lead to interlock the halogen-containing fluid source.

At step 315, additional silicon-containing precursor may be flowed (and/or caused to flow) through the valve and into the exhaust conduit while the halogen-containing fluid source remains interlocked such that no halogen-containing fluid flows from the halogen-containing source to the exhaust conduit.

At step 317, the valve member may be moved (e.g., by a user and/or an actuator) to the closed position. The valve member may be moved to the closed position, such that the valve-closed switch closes (and/or is caused to close) and the second mechanical switch moves (and/or is caused to move) to the closed position such that the second end of the signal lead is electrically connected to the first end of the signal lead by both the first mechanical switch and the second mechanical switch.

At step 319, the halogen-containing fluid may be flowed (and/or caused to flow) into the exhaust conduit, for example, to remove silicon-containing precursors and/or residue from within the exhaust conduit without backflowing the halogen-containing fluid into a chamber body (e.g., chamber body 104) coupled to the exhaust conduit by the manual valve.

FIG. 4 shows example elements of a controller 174. The controller 174 may include one or more processors 402, which may execute instructions stored in the random-access memory (RAM) 404, the removable media 410 (such as a Universal Serial Bus (USB) drive, compact disk (CD) or digital versatile disk (DVD), or floppy disk drive), or any other desired storage medium. Instructions may also be stored in an attached (or internal) hard drive 406. The instructions, when executed, may cause the one or more processors 402 to configure the controller 174 to perform or cause performance of one or more steps and/or operations described herein. The controller 174 may also include a security processor (not shown), which may execute instructions of one or more computer programs to monitor the processes executing on the processor 402 and any process that requests access to any hardware and/or software components of the controller 174 (e.g., ROM 408, RAM 404, the removable media 410, the hard drive 406, a network interface (e.g., I/O) 412, etc.). The controller 174 may include one or more output devices, such as the user interface 414 (e.g., a screen, a display device, a monitor, etc.), and may include one or more output device controllers, such as a video processor. There may also be one or more user input devices 416, such as, keyboard, mouse, touch screen, microphone, etc. The controller 174 may also include one or more network interfaces, such as a network interface 412, which may be a wired interface, a wireless interface, or a combination of the two. The network interface 412 may provide an interface for the controller 174 to communicate with a network 418 (e.g., a RAN, or any other network). The network interface 412 may include a modem, and the network 418 may include communication links, an external network, a provider's wireless, coaxial, fiber, or hybrid fiber/coaxial distribution system, or any other desired network. Additionally, the controller 174 may include drive module 130 in communication with the one or more processors 402. Alternatively, the drive module 130 may be external to the controller 174 and may include hardware, software, or a combination of both, and in communication with the controller 174. Additionally, the controller 174 may include one or more device interfaces 420 for interfacing and/or communicating with one or more external devices.

The example in FIG. 4 may be a hardware configuration, although the components shown may be implemented as software and/or a combination of hardware and software as well. Modifications may be made to add, remove, combine, divide, etc. components of the controller as desired. Additionally, the components may be implemented using basic computing devices and components, and the same components (e.g., processor 402, ROM storage 408, user interface 414, etc.) may be used to implement any of the other computing devices and components described herein. For example, the various components described herein may be implemented using computing devices having components such as a processor executing computer-executable instructions stored on a computer-readable medium, as shown in FIG. 4. Some or all of the entities described herein may be software based, and may co-exist in a common physical platform (e.g., a requesting entity may be a separate software process and program from a dependent entity, both of which may be executed as software on a common computing device).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. An interlock arrangement, comprising:
a signal lead having a first end and a second end;
a first mechanical switch coupled to the first end of the signal lead, the first mechanical switch having a normally-closed position and an open position; and
a second mechanical switch coupling the first mechanical switch to the second end of the signal lead, the second mechanical switch having a normally-open position and a closed position.

2. The interlock arrangement of claim 1, further comprising a first relay including the first mechanical switch, the first relay further comprising:
a first relay housing enclosing the first mechanical switch; and
a first relay coil arranged within the first relay housing configured to move the first mechanical switch between the normally-closed position and the open position when energized.

3. The interlock arrangement of claim 2, further comprising:
a power supply lead connected to the first relay coil; and
a power return lead coupled to the first relay coil and therethrough to the power supply lead.

4. The interlock arrangement of claim 3, further comprising a valve-open switch coupled to the power return lead and configured to electrically couple the power return lead to the first relay when a manual valve is moved to a valve open position.

5. The interlock arrangement of claim 2, wherein the first relay further comprises a first paired mechanical switch arranged within the first relay housing, the first paired mechanical switch having a normally-open position and a closed position, the first relay coil configured to move the first paired mechanical switch between the normally-open position and the closed position when energized.

6. The interlock arrangement of claim 1, further comprising a second relay including the second mechanical switch, the second relay further comprising:
a second relay housing enclosing the second mechanical switch; and
a second relay coil arranged within the second relay housing configured to move the second mechanical switch between the normally-open position and the closed position when energized.

7. The interlock arrangement of claim 6, further comprising:
a power supply lead connected to the second relay coil; and
a power return lead coupled to the second relay coil and therethrough to the power supply lead.

8. The interlock arrangement of claim 7, further comprising a valve closed switch coupled to the power return lead and configured to electrically couple the power return lead to the second relay when a manual valve is moved to a valve closed position.

9. The interlock arrangement of claim 6, wherein the second relay further comprises a second paired mechanical switch arranged within the second relay housing, the second paired mechanical switch having a normally-open position and a closed position, the second relay coil configured to move the second paired mechanical switch between the normally-open position and the closed position when energized.

10. The interlock arrangement of claim 1, further comprising:
a manual valve including:
a valve body having an inlet port and an outlet port;
a valve member supported for movement within the valve body between an open position and a closed position, the inlet port fluidly coupled to the outlet port in the open position, the inlet port fluidly separated from the outlet port in the closed position;
a valve-open switch operably associated with the valve member and configured to electrically close when the valve member is in the open position; and
a valve-closed switch operably associated with the valve member and configured to electrically close when the valve member is in the closed position,
wherein the valve-open switch is operably associated with the first mechanical switch, wherein the valve-closed switch is operably associated with the second mechanical switch, and wherein both the valve-open switch and the valve-closed switch are electrically open when the valve member is between the open position and the closed position.

11. The interlock arrangement of claim 1, further comprising:
a signaling relay including:
a signaling relay housing;
a mechanical signaling switch arranged within the signaling relay housing and coupling the first end of the signal lead to the first mechanical switch, the mechanical signaling switch having a normally-open position and a closed position; and
a signaling coil arranged within the signaling relay housing and configured to move the mechanical signaling switch to the closed position when energized;
a signaling supply lead connected to the signaling coil and configured to couple the signaling coil to a current source; and
a signaling return lead connected to the signaling coil and therethrough to the signaling supply lead, the signaling return lead configured to couple the signaling coil to the current source.

12. The interlock arrangement of claim 1, further comprising a halogen-containing fluid source coupled to the second end of the signal lead and therethrough to the first end of the signal lead through the first mechanical switch and the second mechanical switch, the halogen-containing fluid source configured to flow a halogen-containing fluid to a semiconductor processing system when both the first mechanical switch and the second mechanical switch electrically connect the first end of the signal lead to the second end of the signal lead.

13. A semiconductor processing system, comprising:
a chamber body coupled to an exhaust source by an exhaust conduit;
a substrate support arranged within the chamber body and supported for rotation therein for rotation about a rotation axis;
a union along the exhaust conduit and coupling a halogen-containing fluid source to the exhaust conduit;
a manual valve arranged along the exhaust conduit between the chamber body and the union, the manual valve including:
a valve body having an inlet port and an outlet port; and
a valve member supported for movement within the valve body between an open position and a closed position, the inlet port fluidly coupled to the outlet port in the open position, the inlet port fluidly separated from the outlet port in the closed position; and
an interlock arrangement as recited in claim 1, the interlock arrangement further comprising:
a valve-open switch operably associated with the valve member and configured to electrically close when the valve member is in the open position; and
a valve-closed switch operably associated with the valve member and configured to electrically close when the valve member is in the closed position,
wherein the valve-open switch is operably associated with the first mechanical switch, wherein the valve-closed switch is operably associated with the second mechanical switch, and wherein both the valve-open switch and the valve-closed switch are electrically open when the valve member is between the open position and the closed position.

14. The semiconductor processing system of claim 13, further comprising:
a silicon-containing precursor source coupled to the exhaust conduit by the chamber body, the silicon-containing precursor source including a silicon-containing precursor selected from a group consisting of silane, disilane, trisilane, dichlorosilane, and trichlorosilane; and
wherein the halogen-containing fluid source includes a halogen-containing fluid selected from a group consisting of hydrochloric acid, chlorine gas, and chlorine trifluoride.

15. The semiconductor processing system of claim 13, further comprising:
a mechanical signaling switch coupling the first end of the signal lead to the first mechanical switch;
a power source coupled to the first end of the signal lead;
a controller operatively coupled to the mechanical signaling switch and responsive to instructions recorded on a memory to:
receive a user input from user input; and
electrically couple the power source to the first mechanical switch using the mechanical signaling switch responsive to the user input to flow a halogen-containing fluid to the union,
whereby one of the first mechanical switch or the second mechanical switch electrically separates the power source from the second end of the signal lead when the valve member is not at the closed position to interlock flow of the halogen-containing fluid to the exhaust conduit.

16. A method of interlocking a halogen-containing fluid source, comprising:
at an interlock arrangement including a signal lead having a first end and a second end; a first mechanical switch coupled to the first end of the signal lead, the first mechanical switch having a normally-closed position and an open position; and a second mechanical switch coupling the first mechanical switch to the second end of the signal lead, the second mechanical switch having a normally-open position and a closed position,
receiving a user input at a user input of a controller;
responsive to receipt of the user input, applying a voltage to the first end of the signal lead to flow a halogen-containing fluid from the halogen-containing fluid source;
flowing no halogen-containing fluid from the halogen-containing fluid source when the first mechanical switch is in the open position and/or the second mechanical switch is in the normally-open position; and
flowing the halogen-containing fluid when the first mechanical switch is in the normally-closed position and the second mechanical switch is in the closed position by electrically coupling the second end of the signal lead to the first end of the signal through the first mechanical switch and the second mechanical switch.

17. The method of claim 16, wherein interlock arrangement includes a valve-open switch and a valve-closed switch operably associated with a valve member of a manual valve arranged along an exhaust conduit, the method further comprising:
moving the valve member to the open position such that the valve-open switch closes, whereby the second mechanical switch remains in the normally-open position and the second mechanical switch separates the second end of the signal lead from the first end of the signal lead to interlock the halogen-containing fluid source; and
flowing a silicon-containing precursor through the manual valve and into the exhaust conduit while the halogen-containing fluid source is interlocked such that no halogen-containing fluid flows from the halogen-containing fluid source to the exhaust conduit.

18. The method of claim 17, further comprising:
moving the valve member from the open position to a location intermediate the open position and the closed position, whereby the valve-open switch opens and the second mechanical switch remains in the normally-open position and the second mechanical switch separates the second end of the signal lead from the first end of the signal lead to interlock the halogen-containing fluid source; and
flowing additional silicon-containing precursor through the manual valve and into the exhaust conduit while the halogen-containing fluid source remains interlocked such that no halogen-containing fluid flows from the halogen-containing fluid source to the exhaust conduit.

19. The method of claim 17, further comprising:
moving the valve member to the closed position, whereby the valve-closed switch closes and the second mechanical switch moves to the closed position such that the second end of the signal lead is electrically connected to the first end of the signal lead by both the first mechanical switch and the second mechanical switch; and
flowing the halogen-containing fluid into the exhaust conduit to remove silicon-containing precursor and/or residue from within the exhaust conduit without backflowing the halogen-containing fluid into a chamber body coupled to the exhaust conduit by the manual valve.

20. An interlock kit for a halogen-containing fluid source, comprising:
a signal lead having a first end and a second end, the first end of the signal lead configured to couple a power source, the second end of the signal lead configured to couple to the halogen-containing fluid source;
a first mechanical switch configured to couple to the first end of the signal lead, the first mechanical switch having a normally-closed position and an open position; and
a second mechanical switch configured to couple the first mechanical switch to the second end of the signal lead, the second mechanical switch having a normally-open position and a closed position.
